(19) United States
(12) Patent Application Publication
(10) Pub. No.: US 2006/0006420 A1
(43) Pub. Date: Jan. 12, 2006

(54) Semiconductor device and a CMOS integrated circuit device

(75) Inventor: Kenichi Goto, Hsin-Chu (TW)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/020,578

(22) Filed: Dec. 27, 2004

(30) Foreign Application Priority Data
Jul. 8, 2004 (JP) 2004-202201

(51) Int. Cl. H01L 27/10

(52) U.S. Cl. 257/204

(57) ABSTRACT

A semiconductor device includes a stress-accumulating insulation film formed on a semiconductor substrate so as to cover a gate electrode and sidewall insulation films, the stress-accumulating insulation film accumulating a stress therein, wherein the stress-accumulating insulation film including a channel part covering the gate electrode and the sidewall insulation films and outer parts extending outside of the channel part, the stress-accumulating insulation film having an increased thickness in the channel part as compared with the outer part.

### CROSS-REFERENCE TO RELATED APPLICATION

The present application is based on Japanese priority application No. 2004-202201 filed on Jul. 8, 2004, the entire contents of which are hereby incorporated by reference.

### BACKGROUND OF THE INVENTION

The present invention generally relates to semiconductor devices and more particularly to an ultra high-speed semiconductor device including a CMOS circuit.

A CMOS circuit has a construction connecting an n-channel MOS transistor and a p-channel MOS transistor in series and is used in various ultra high-speed processors as a fundamental element of the high-speed logic circuit.

In recent ultra high-speed processors, the gate length of the p-channel MOS transistor and the n-channel MOS transistor constituting a CMOS circuit is reduced to 0.1 μm or less. Thus, a MOS transistor having a gate length of 90 nm or less, such as 50 nm, for example, is fabricated.

With such ultra high-speed MOS transistors having the gate length of 90 nm or less designed for use with recent CMOS circuits, it is known that the carrier mobility changes significantly with the stress applied to a channel region thereof. Such a stress in the channel region is caused primarily by the SiN etching stopper film typically provided so as to cover the gate electrode for the purpose of formation of a via contact.

FIG. 1 shows the schematic construction of a MOS transistor 10 having an SiN film.

Referring to FIG. 1, there is formed a gate electrode 13 on a silicon substrate 11 in correspondence to a channel region via a gate insulation film 12, and LDD regions 11a and 11b are formed in the silicon substrate 11 at both lateral sides of the gate electrode 13.

Further, sidewall insulation films 13A and 13B are formed at both lateral sides of said gate electrode, and source-drain diffusion regions 11c and 11d are formed at outer sides of the sidewall insulation films 13A and 13B, respectively, in overlapping relationship with the LDD regions 11a and 11b.

Further silicide layers 14A and 14B are formed on the surface part of the source/drain diffusion regions 11c and 11d, and a silicide layer 14C is formed on the gate electrode 13.

Further, with the construction of FIG. 1, there is formed an SiN film 15 accumulating therein a tensile strength on the silicon substrate 11 so as to cover the gate structure that includes the gate electrode 13, the sidewall insulation films 13A and 13B, and the silicide layer 14.

It should be noted that such a tensile stress film 15 performs the function of pushing the gate electrode 13 toward the silicon substrate 11, and as a result, there is caused a compressive stress yy acting in the vertical direction and a tensile stress xx acting in the lateral direction right underneath the gate electrode 13.

FIG. 2 shows the change rate of saturated drain current of an n-channel MOS transistor and a p-channel MOS transistor for the case a compressive stress is thus applied to the channel region.

Referring to FIG. 2, the change rate of the saturated drain current of a MOS transistor takes a positive value in the case the MOS transistor is an n-channel MOS transistor, and thus, the current drivability of the n-channel MOS transistor increases with the thickness of the SiN film 15. In the case the MOS transistor is a p-channel MOS transistor, on the other hand, the change rate takes a negative value, and the current drivability decreases slightly with the thickness of the SiN film 15. Further, it can be seen that the magnitude of the change rate of the current with regard to the thickness of the SiN film 15 is much larger in the case the MOS transistor is an n-channel MOS transistor as compared with the case in which the MOS transistor is a p-channel MOS transistor.

While FIG. 2 is not represented with a scale, there is a research reporting that the saturated drain current can be increased by about 10% by using a film accumulating the tensile stress of 1.5 GPa for the SiN film 15 and by forming such an SiN film with the thickness of 80 nm.

(Non-Patent Reference 1) Ghani, T., et al., IEDM 03, 978-980, Jun. 10, 2003

(NON-Patent Reference 2) K. Mistry, et al., Delaying Forever: Uniaxial Strained Silicon Transistors in a 90 nm CMOS Technology, 2004 Symposium on VLSI Technology, pp. 50-51

### SUMMARY OF THE INVENTION

The result of FIG. 2 indicates that, in the case of an n-channel MOS transistor), it is possible to increase further the carrier mobility of the channel region, and hence the operational speed of the MOS transistor, by controlling the compressive stress applied to the channel region in the direction perpendicular to the substrate surface, by the thickness of the SiN film 15.

On the other hand, in the case a compressive stress is applied to the channel region like this, there arises a problem that the carrier mobility is decreased in the p-channel MOS transistor as shown in FIG. 2.

Thus, in the construction of FIG. 1 in which the SiN tensile stress film 15 is formed uniformly over the MOS transistors, there arise situations, in the case the semiconductor integrated circuit device includes not only n-channel MOS transistors but also p-channel MOS transistors, in that the current drivability becomes unbalanced between the n-channel MOS transistor and the p-channel MOS transistor, and it becomes possible to construct a CMOS circuit.

For example, in the case an SiN film accumulating therein a tensile stress of 1.5 GPa is used as the SiN film 15 with a thickness of 80 nm, there is caused a decrease of drain current in the p-channel MOS transistor with the magnitude of as much as about 3%.

Further, in the case of generating such a compressive stress with the SiN film 15, the inventor of the present invention has discovered, in the investigation that uses simulation and constitutes the foundation of the present invention, that the value of the stress caused in the channel region is increased at the beginning with the thickness of the SiN film but the magnitude of increment starts to decrease when the thickness of the SiN film has exceeded about 20 nm as shown in FIG. 3. When the thickness had exceeded 80 nm, there is caused a substantial saturation.

Referring to FIG. 3, the vertical axis represents the magnitude of the stress in the channel region in the structure of FIG. 1, while the horizontal axis represents the thickness of the SiN film 15. Further, in FIG. 3, “xx” represents the tensile stress shown in FIG. 1, in other words the tensile stress working in the in-plane direction of the substrate, while yy represents the compressive stress working in the vertical direction, in other words, the direction perpendicular to the substrate surface.

Thus, in the construction of FIG. 1, there is obtained no substantial increase of the current drivability in an n-channel MOS transistor when the thickness of the SiN film is increased beyond the thickness of 80 nm.

Further, in relation to the situation in that the MOS transistor 10 of FIG. 1 is generally formed on a silicon wafer in the form of an integrated circuit, such formation of the SiN film accumulating a tensile stress on the MOS transistor with large thickness may invite the problem shown in FIG. 4 in that a flat silicon wafer W is warped as a result of the formation of the thick SiN film 15. Particularly, with the silicon wafer of 300 nm diameter used currently for mass production of semiconductor integrated circuits, there is caused a large warp, leading to various serious problems such as cracking of the wafer or difficulty of the wafer handling such as wafer transportation.

FIG. 5 shows the amount of warp of the 300 mm-diameter silicon wafer on which the MOS transistors 10 of FIG. 1 are formed and the thickness of the SiN film 15.

Referring to FIG. 5, it can be seen that the amount of warp exceeds the allowable limit value of 60 μm determined from the request of wafer handling when the thickness of the SiN film 15 exceeds 110 nm.

The result of FIG. 5 indicates that it is not possible to increase the thickness of the SiN film 15 beyond 110 nm in the MOS transistor of FIG. 1 that has the SiN film 15, and thus, it is not possible to realize the compressive stress exceeding well over 0.4 GPa right underneath the gate electrode 13. Associated with this, it is not possible to achieve the improvement of the device characteristics with the n-channel MOS transistor 10.

In a first aspect of the present invention, there is provided a semiconductor device, comprising:
a semiconductor substrate;
a gate electrode formed on a channel region in said semiconductor substrate via a gate insulation film; and
a pair of diffusion regions formed in said semiconductor substrate at both lateral sides of said gate electrode,
a pair of sidewall insulation films being formed on both sidewall surfaces of said gate electrode,
a stress-accumulating insulation film being formed on said semiconductor substrate so as to cover said gate electrode and said sidewall insulation films,
said stress-accumulating insulation film accumulating a stress therein,
said stress-accumulating insulation film including a channel part covering said gate electrode and said sidewall insulation films and outer parts extending outside of said channel part,
said stress-accumulating insulation film having an increased thickness in said channel part as compared with said outer part.

In another aspect of the present invention, there is provided a CMOS integrated circuit, comprising:
a semiconductor substrate defined with a first device region and a second device region by a device isolation region;
an n-channel MOS transistor formed in said first device region; and
a p-channel MOS transistor formed in said second device region,
said n-channel MOS transistor comprising: a first gate electrode formed on a first channel region in said first device region via a first gate insulation film; a pair of first sidewall insulation films respectively covering both sidewall surfaces of said first gate electrode; and a pair of n-type diffusion regions formed in said semiconductor substrate at both lateral sides of said first gate electrode;
said p-channel MOS transistor comprising: a second gate electrode formed on a second channel region in said second device region via a second gate insulation film; a pair of second sidewall insulation films respectively covering both sidewall surfaces of said second gate electrode; and a pair of p-type diffusion regions formed in said semiconductor substrate at both lateral sides of said second gate electrode;
wherein there is formed a stress-accumulating insulation film accumulating therein a tensile stress in said first device region so as to cover said first gate electrode and said first sidewall insulation films,
said stress-accumulating insulation film comprising a channel part covering said first gate electrode and said first sidewall insulation films and an outer part outside of said channel part,
said stress-accumulating insulation film having an increased thickness in said channel part as compared with said outer part.

In a further aspect of the present invention, there is provided a semiconductor device, comprising:
a semiconductor substrate;
a gate electrode formed on a channel region in said semiconductor substrate via a gate insulation film; and
a pair of diffusion regions formed in said semiconductor substrate at both sides of said gate electrode,
wherein there are formed sidewall insulation films on both sidewall surfaces of said gate electrode, and
wherein there is formed a stress-accumulating insulation film accumulating therein a stress so as to cover said gate electrode and said sidewall insulation films, said stress-accumulating insulation film having a laminated structure in which plural insulation films each accumulating a stress having a common sign are laminated.

According to the present invention, it becomes possible to apply a stress selectively to the channel region right underneath the gate electrode, by locally increasing the thickness of the stress-accumulating insulation film formed so as to cover the gate electrode in corresponding to a part covering the gate electrode. Thereby, the current drivability of the MOS transistor is increased and the operation al speed is improved. Further, in the case there are provided other MOS transistors having the channel of opposite conductivity on the same semiconductor device, such a construction can reduce or eliminate the problem of decrease of the current drivability of such other MOS transistors caused by the stress originating from the stress-accumulating insulation film.

Further, according to the present invention, the stress-accumulating insulation film is formed on the semiconductor substrate selectively and locally in the vicinity of the gate electrode of a MOS transistor of a specific conductivity type channel. Thereby, the warp of the semiconductor wafer, on which such MOS transistors are formed, is suppressed, while this allows formation of the stress-accumulating insulation film with increased thickness as compared with the conventional devices.

Further, because the foregoing stress-accumulating insulation film is formed with a small thickness or not formed at all except for the part covering the gate electrode, there arises a possibility, in the case such a stress-accumulating insulation film is used for an etching stopper film at the time of formation of a contact hole to the diffusion region, that the surface of the diffusion region may be damaged at the time of the contact hole formation. Thus, in order to avoid such a problem, the present invention forms another insulation film capable of functioning as an etching stopper, on the stress-accumulating insulation film as an etching stopper film.

Particularly, according to the present invention, it becomes possible, in a CMOS semiconductor integrated circuit device in which an n-channel MOS transistor and a p-channel MOS transistor are integrated on a common semiconductor substrate, to improve the characteristics of the n-channel MOS transistor without deteriorating the characteristics of the p-channel MOS transistor, by locally forming a stress-accumulating insulation film accumulating a tensile stress in the vicinity of the gate electrode of the n-channel MOS transistor so as to cover the gate electrode. Particularly, by forming the diffusion region of the p-channel MOS transistor by using a SiGe mixed crystal, it becomes possible to induce a compressive stress acting laterally to the channel region of the p-channel MOS transistor, and it becomes possible to improve the operational speed of the p-channel MOS transistor. Thereby, it becomes possible to realize a CMOS device in which the characteristics of the p-channel MOS transistor and the n-channel MOS transistor are balanced.

In this case, too, it becomes possible to perform the process of forming contact holes to respective diffusion regions of the n-channel MOS transistor and the p-channel MOS transistor stably and with excellent yield, by forming another insulation film capable of performing as an etching stopper, such that such another insulation film covers both the n-channel MOS transistor and the p-channel MOS transistor.

Particularly, by forming the stress-accumulating insulation film in the form of lamination of thin stress-accumulating insulation film elements, it becomes possible to increase the stress accumulated in the film, and hence the stress applied to the channel region, without increasing the overall thickness of the stress-accumulating insulation film.

Other objects and further features of the present invention will become apparent from the following detailed description when read in conjunction with the attached drawings.

### BRIEF DESCRIPTION OF THE DRAWINGS

FIG. 1 is a diagram showing the construction of a conventional MOS transistor having a stress-accumulating insulation film;

FIG. 2 is a diagram qualitatively showing the relationship between the thickness of the stress-accumulating insulation film and the change ratio of saturated drain current for an n-channel MOS transistor and a p-channel MOS transistor;

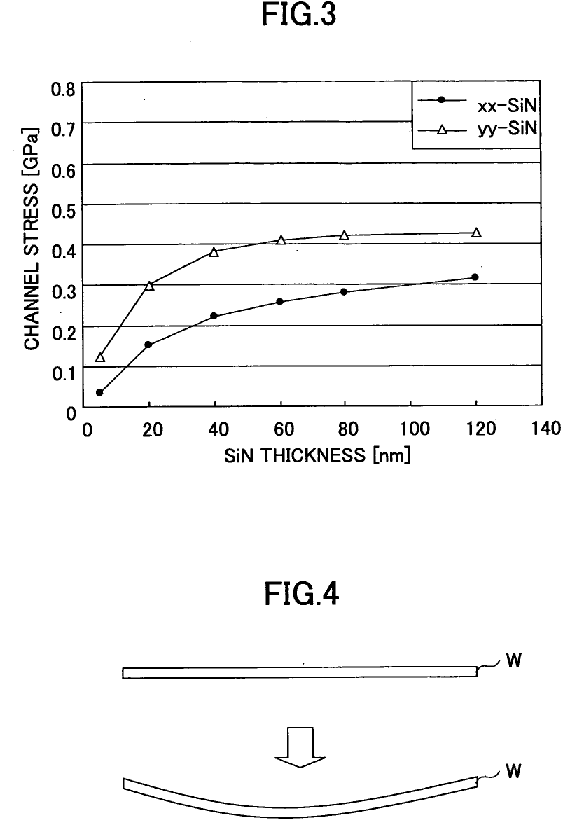

FIG. 3 is a diagram showing the relationship between the thickness of the stress-accumulating insulation film and the stress inducted in the channel region in the structure of FIG. 1;

FIG. 4 is a diagram explaining the problem of warp of silicon wafer associated with formation of a stress-accumulating insulation film;

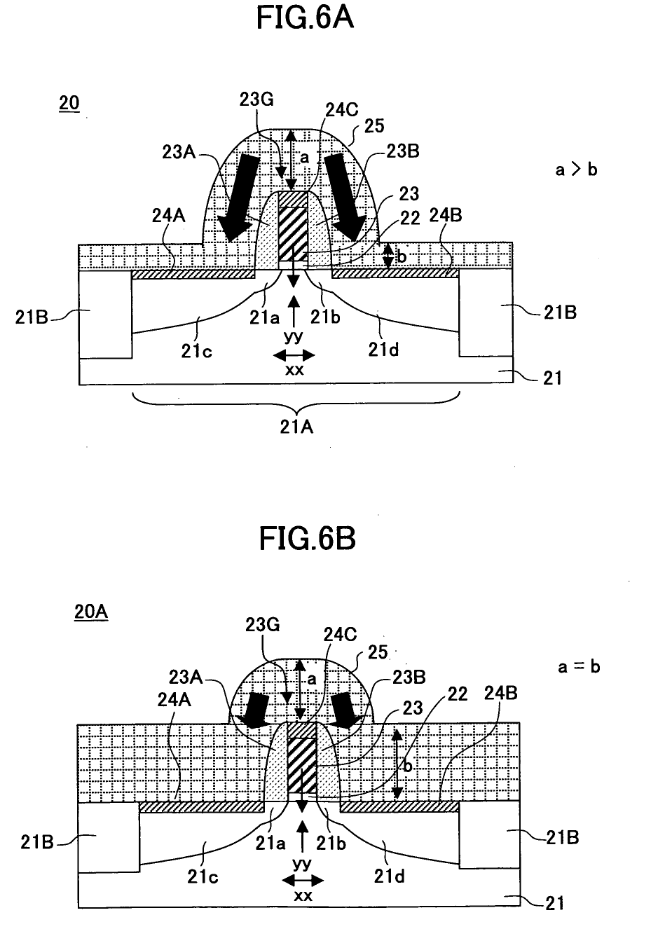

FIG. 5 is a diagram showing the relationship between the thickness of the stress-accumulating insulation film and the magnitude of the warp of the silicon wafer;

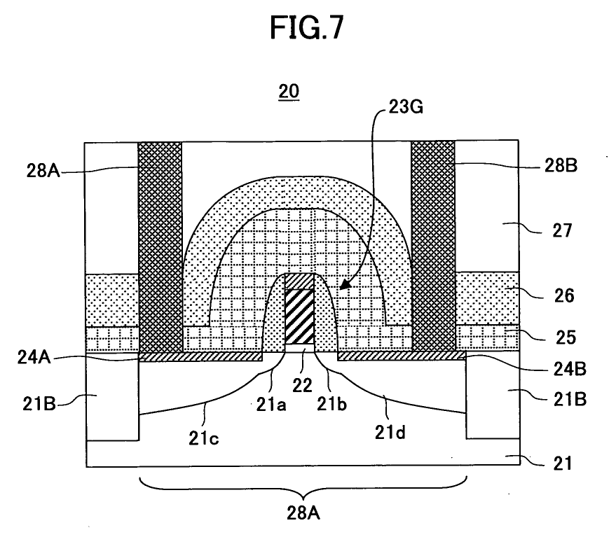

FIGS. 6A and 6B are diagrams showing the construction of an n-channel MOS transistor according to a first embodiment of the present invention in comparison with a conventional construction;

FIG. 7 is a diagram showing the construction of the n-channel MOS transistor according to the first embodiment including an interlayer insulation film and contact plugs;

FIG. 8 is a diagram showing the relationship between the thickness of the stress-accumulating insulation film and the channel stress for the n-channel MOS transistor of FIG. 7;

FIG. 9 is a diagram showing the relationship between the saturated drain current and threshold voltage for the n-channel MOS transistor of FIGS. 6 and 7 in comparison with that of the conventional MOS transistor of FIG. 1;

FIGS. 10A-10E are diagrams showing the fabrication process of the n-channel MOS transistor of FIG. 7;

FIG. 11 is a diagram showing the problem encountered in the fabrication process of the MOS transistor of FIG. 1;

FIGS. 12A and 12B are diagrams explaining how the first embodiment of the present invention avoids the problem of FIG. 11;

FIG. 13 is a diagram showing the construction of the n-channel MOS transistor of FIG. 7 in a plan view;

FIG. 14 is a diagram showing the saturated drain current for the case a large number of n-channel MOS transistor of FIG. 7 are integrated close with each other;

FIG. 15 is a diagram showing the construction of a CMOS device according to a second embodiment of the present invention;

FIG. 16 is a diagram showing the CMOS device of FIG. 15 in the state in which there are formed an interlayer insulation film and contact plugs;

FIG. 17 is a diagram showing a modification of the CMOS device of FIG. 15;

FIG. 18 is a diagram showing the construction of a CMOS device according to a third embodiment of the present invention;

FIG. 19A-19C are diagrams showing the principle of a fourth embodiment of the present invention;

FIG. 20 is another diagram showing the principle of the fourth embodiment;

FIG. 21 is a further diagram showing the principle of the fourth embodiment;

FIGS. 22A-22D are diagrams showing the fabrication process of an n-channel MOS transistor according to a fourth embodiment of the present invention;

FIG. 23 is a diagram showing the construction of an n-channel MOS transistor according to a fifth embodiment of the present invention.

### DETAILED DESCRIPTION OF THE INVENTION

### First Embodiment

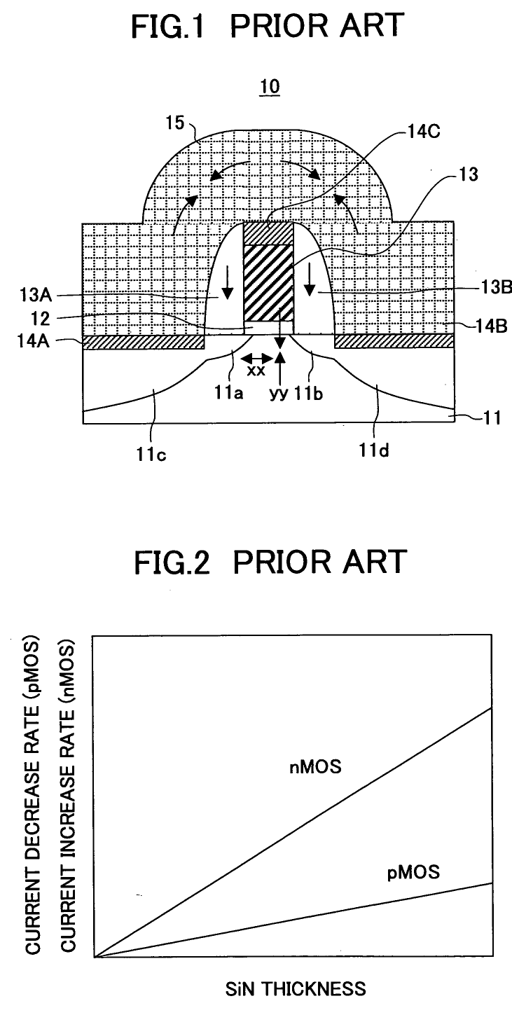

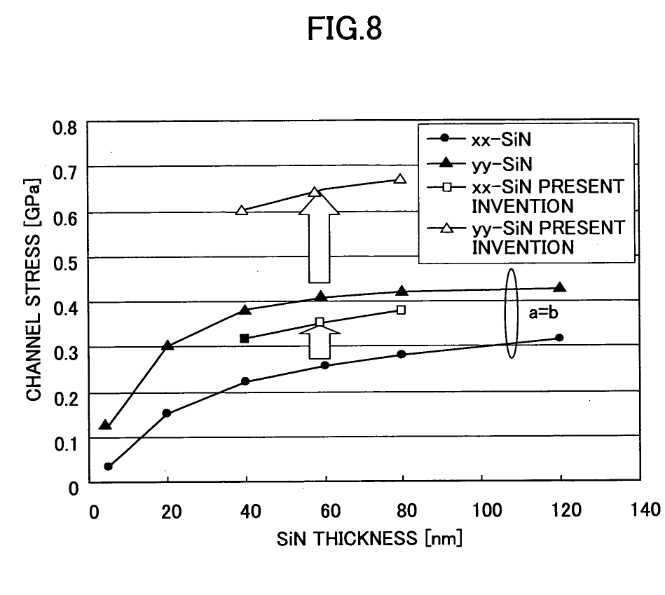

FIG. 6A shows the construction of an n-channel MOS transistor 20 having a gate length of 37 nm according to a first embodiment of the present invention, while FIG. 6B shows the construction of an n-channel MOS transistor 20A having the identical construction as the MOS transistor 10 of FIG. 1 for the purpose of comparison and for the purpose of explanation of the MOS transistor 20 of FIG. 6A, wherein it should be noted that FIG. 6B shows the transistor 20A by using the same reference numerals used with FIG. 6A.

Referring to FIG. 6A, there is defined a device region 20A for the n-channel MOS transistor 20 on a silicon substrate 21 by a device isolation region 21B of STI type, and a gate electrode 23 is formed on the device region 20A via an SiON gate insulation film 22.

Further, there are formed n-type LDD regions 21a and 21b in the silicon substrate 21 at both lateral sides of the gate electrode 23, and source and drain diffusion regions 21c and 21d of n+-type are formed in the silicon substrate 21 at outer sides of the sidewall insulation films 23A and 23B formed on both sidewall surfaces of the gate electrode 23.

Further, there are formed cobalt silicide layers 24A, 24B and 24C respectively on the surface of the n+-type diffusion regions 21c and 21d and also on the gate electrode 23.

Further, in the MOS transistor of FIG. 6A, there is formed an SiN film 25 accumulating therein a tensile stress of 1.0 GPa or more, typically 1.5 GPa or more, by a LPCVD (low-pressure CVD) process conducted at a substrate temperature of 600° C., for example, while supplying a mixed gas of SiCl₂H₂ and NH₃ as a source gas, such that the SiN film 25 covers a gate structure 23G formed of the gate electrode 23 carrying thereon the cobalt silicide layer 24C and the sidewall insulation films 23A and 23B.

The SiN film 25 thus having the strong tensile stress functions so as to urge the gate structure 23G contacting therewith toward the silicon substrate 21 as indicated in FIG. 6A by an arrow, and as a result, there is applied a compressive stress to the channel region formed in the silicon substrate 21 right underneath the gate electrode 23 such that the compressive stress works perpendicularly to the substrate surface.

In the construction of FIG. 6A, it should be noted that the SiN film 25 is etched at outside of the part that covers the gate structure by using a mask process to be explained later, and as a result, the SiN film 25, while having a thickness a in the part immediately above the gate electrode 23, has a reduced thickness b smaller than the foregoing thickness a in the foregoing outer part (a>b). Thereby, it should be noted that the thickness b in the foregoing outer part may be zero, and in this case, the SiN film 25 is etched away in such an outer part. In the illustrated example, the SiN film 25 is deposited with the thickness of 60 nm and is etched by 40 nm in the foregoing outer part. As a result, in the example of FIG. 6A, the thickness a takes the value of 60 nm while the thickness takes the value of 20 nm.

In the construction of FIG. 6A, the SiN film having the compressive stress extends in the direction generally perpendicular to the surface of the substrate 21 along the sidewall surface of the gate structure 23G, and thus, the gate structure 23G experiences a large stress in the direction perpendicular to the surface of the substrate 21. Thereby, a large compressive stress yy is formed in the device region 21A right underneath the gate electrode 23 such that the compressive stress yy acts perpendicularly to the surface of the substrate 21.

Contrary to this, in the n-channel MOS transistor 20A of FIG. 6B having the conventional structure, it should be noted that the thickness of the SiN film 25 is generally equal in the part covering the gate structure 23G and in the part covering the outer region of the gate structure 23G, and thus, the thickness a becomes generally equal to the thickness b.

Thus, in such a structure, there is certainly induced a pushing force pushing the gate structure 23G toward the substrate 21 in the direction generally perpendicular to the surface of the substrate 21 by the tensile stress accumulated in the SiN film 25 in the part thereof projecting upward over the gate structure 23G, while in the part of the SiN film 25 lower than the foregoing projecting part, the tensile stress works primarily in the direction generally parallel to the substrate surface, and as a result, only a very small value is obtained for the compressive stress yy acting perpendicularly to the substrate surface as compared with the case of FIG. 6A.

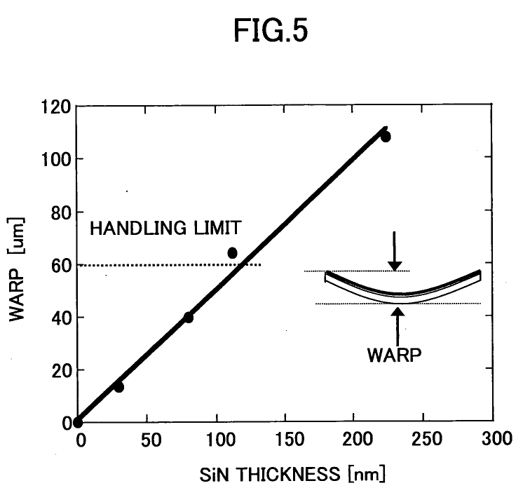

Further, as explained previously with reference to FIG. 3, there occurs a saturation in the compressive stress yy when the thickness of the SiN film 25 is increased beyond 80 mm, and no substantial increase of saturation drain electrode is achieved.

On the other hand, in the structure of FIG. 6A, there can be a case, because of the decreased thickness of the SiN film 25 in the foregoing outer part covering the n-type diffusion regions 21c and 21d, in that the SiN film 25 cannot perform as an effective etching stopper at the time of formation of the contact hole to the diffusion region 21c or 21d.

Thus, in the present invention, a second SiN film 26 is formed on the structure of FIG. 6A with a generally uniform thickness in conformity with the shape of the SiN film 25, as an effective etching stopper film.

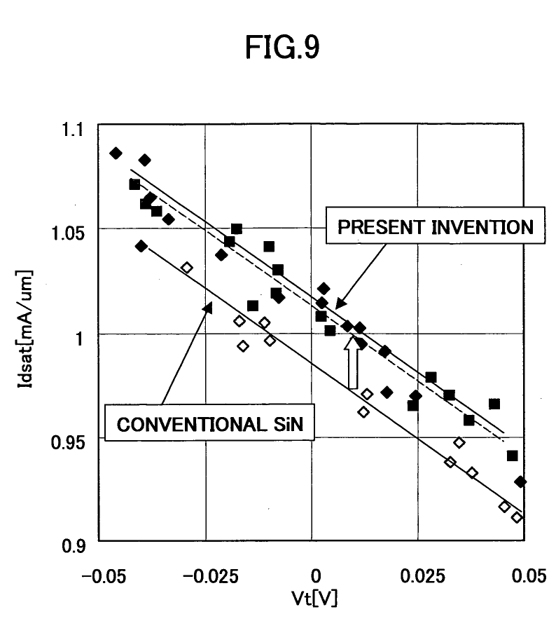

Referring to FIG. 7, the SiN film 26 may be the same SiN film as the film 25 that accumulates therein a tensile stress of 1.5 GPa, wherein it is preferable, in view of the purpose of the SiN film 26 of acting as an effective etching stopper, that the SiN film 26 has a thickness of 30 nm or more. In the illustrated example, the SiN film 26 is formed with the thickness of 80 nm.

Further, in the construction of FIG. 7, there is formed an interlayer insulation film 27 on the SiN film 36, and via plugs 28A and 28B are formed in the interlayer insulation film 27 respectively in contact with the silicide layers 24A and 24B covering the diffusion regions 21c and 21d via the SiN film 26 and the SiN film 25 (in the case the thickness b is not zero).

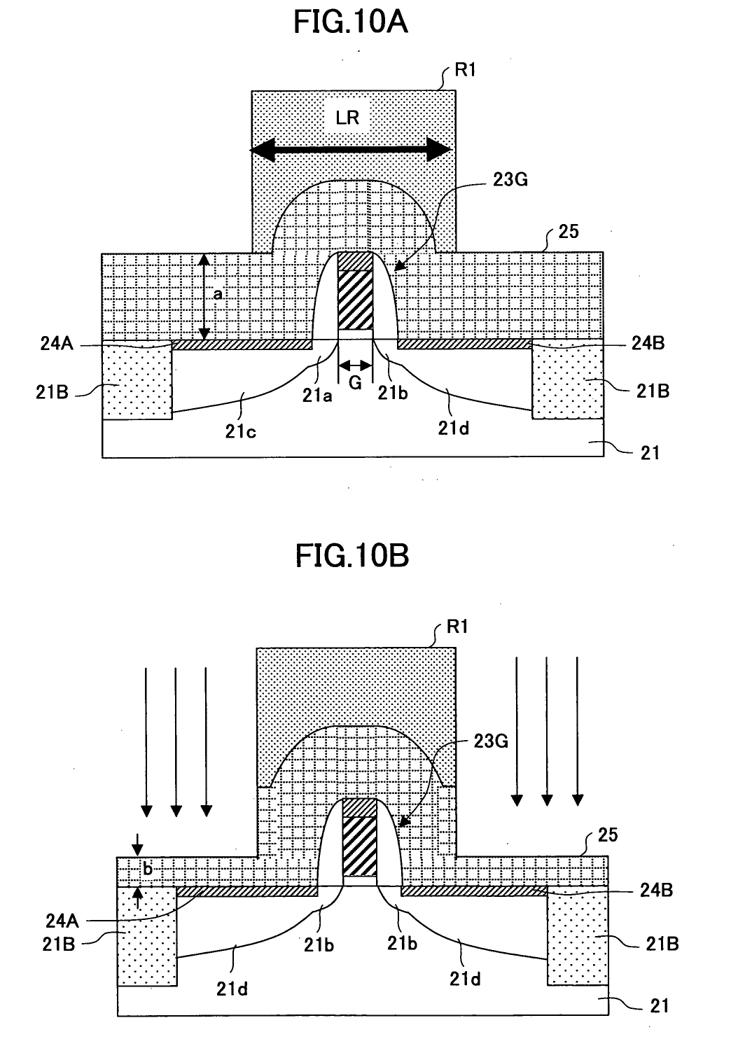

FIG. 8 shows the vertical compressive stress yy and the horizontal tensile stress xx inducted in the channel region for the case the thickness of the SiN film 25 is changed variously within the range of 40-80 nm in the construction of FIG. 7, in comparison with the result of FIG. 3. In FIG. 8, it should be noted that the SiN film 25 is eliminated, in the case the SiN film 25 has the thickness of 40 nm, as a result of the etching conducted with the thickness of 40 nm in the foregoing outer part.

Referring to FIG. 8, it can be seen that the compressive stress yy acting perpendicularly to the substrate surface formed in the channel region is increased significantly from the value of 0.4 GPa in the case of FIG. 3 to the value of 0.6-0.7 GPa. It is believed that this effect is achieved as a result of setting the thickness a to be larger than the thickness b in the construction of FIG. 6A.

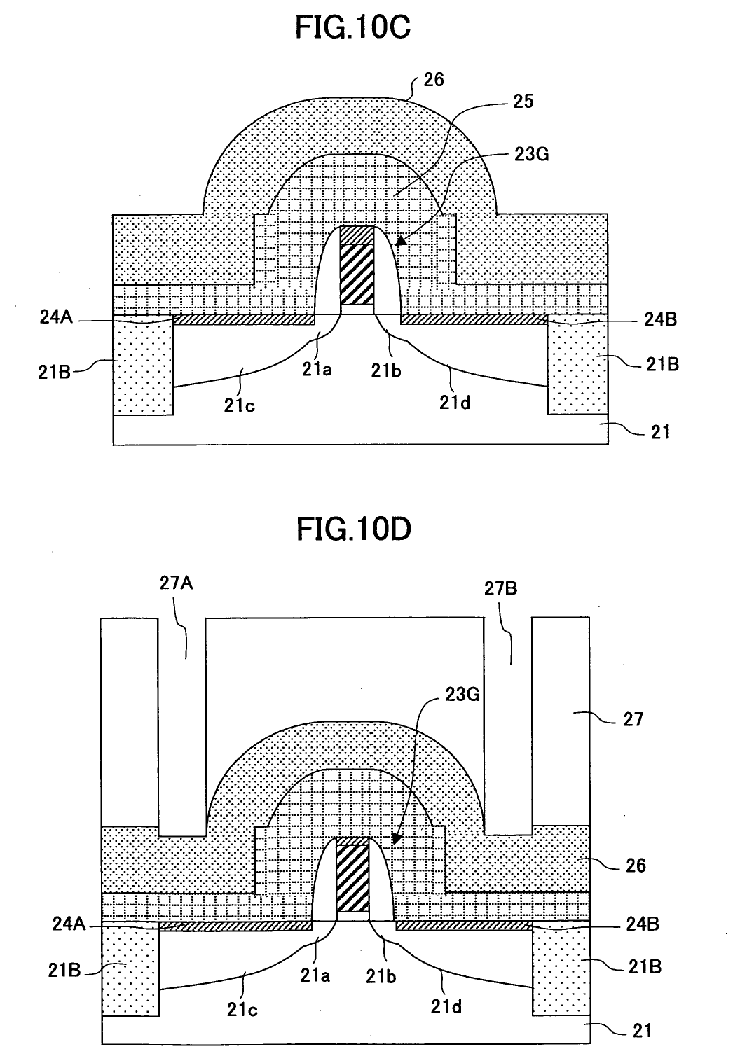

FIG. 9 is a diagram showing the saturated drain current of the n-channel MOS transistor of FIG. 7 in comparison with the saturated drain current of the n-channel MOS transistor having the structure of FIG. 1. In FIG. 9, it should be noted that the vertical axis represents the saturated drain current per a gate width, while the horizontal axis represents the threshold current.

Referring to FIG. 9, as a result of formation of such a stress-accumulating insulation film 25 such that the SiN film 25 is localized in the vicinity of the gate electrode, it will be noted that there is caused an increase of the saturated drain current of 3% as compared with the case of forming the stress-accumulating insulation film 25 of FIG. 6B, in which the stress-accumulating insulation film 25 is over the entire substrate surface. In FIG. 9, it should be noted that ▪ and ♦ represent respectively the case the second SiN film 26 is formed and not formed.

In the construction of FIG. 7, it should be noted that the SiN film 26 is not necessarily be a film accumulating a tensile stress. Thus, it is possible to use a stress-free film or a film accumulating a compressive stress also for the film 26.

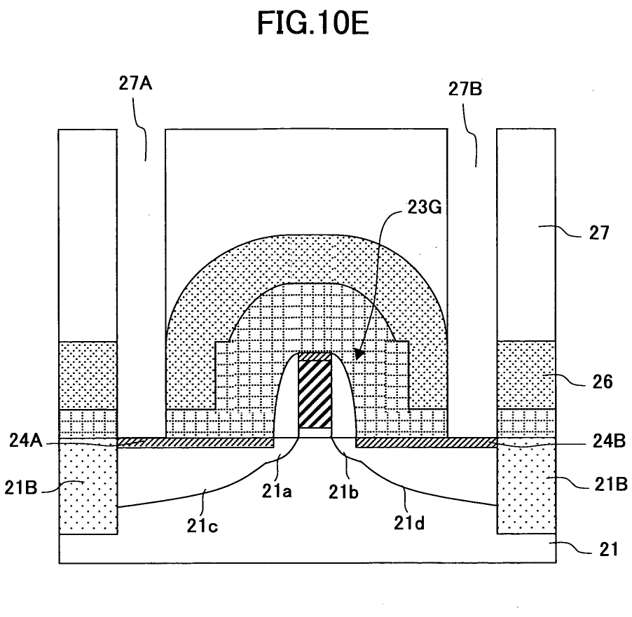

Next, the fabrication process of the n-type MOS transistor 20 of the present embodiment will be explained with reference to FIGS. 10A-10E.

Referring to FIG. 10A, the present embodiment first forms the structure of FIG. 6B and forms a resist pattern R1 having a width LR such that the resist pattern R1 covers the gate structure 23G. Thereby, the width LR is set to be larger than a sum of the width G of the gate electrode 23 and twice the value of the thickness a of the SiN film 25 (LR>G+2a). For example, in the case the gate electrode width G is 40 nm an the thickness a is 60 nm, the width LR of the resist pattern R1 is set to be 160 nm or more, such as 170 nm.

Next, in the step of FIG. 10B, the SiN film 25 is removed by an anisotropic plasma etching process while using the resist pattern R1 as a mask, and the thickness of the SiN film 25 is reduced from the thickness a to the thickness b of FIG. 6A in correspondence to the foregoing outer part.

Finally, in the step of FIG. 10C, the resist pattern R1 of FIG. 10B is removed, and the second SiN film 25 is deposited by an LPCVD process with a thickness of 80 nm, for example, such that a tensile stress of 1.5 GPa is accumulated in the film.

Further, in the step of FIG. 10D, the interlayer insulation film 27 is deposited on the structure of FIG. 10C, followed by a planarization process conducted by a CMP process. Further, contact holes. 27A and 27B are formed in the interlayer insulation film 27 in correspondence to the source and drain diffusion regions 21c and 21d by using a dry etching recipe acting selectively to the SiN film 26, while using a resist pattern not illustrated as a mask.

Further, in the step of FIG. 10E, the same resist pattern is used as a mask, and the SiN films 26 and 25 are removed by a dry etching recipe showing selectively against the silicide layer 24A and the silicon substrate 21. Thereby, the silicide layers 24A and 24B are exposed respectively at the bottom part of the contact holes 27A and 27B.

Further, a structure explained with reference to FIG. 7 is obtained by filling the contact holes 27A and 27B by a conductor such as tungsten.

### Second Embodiment

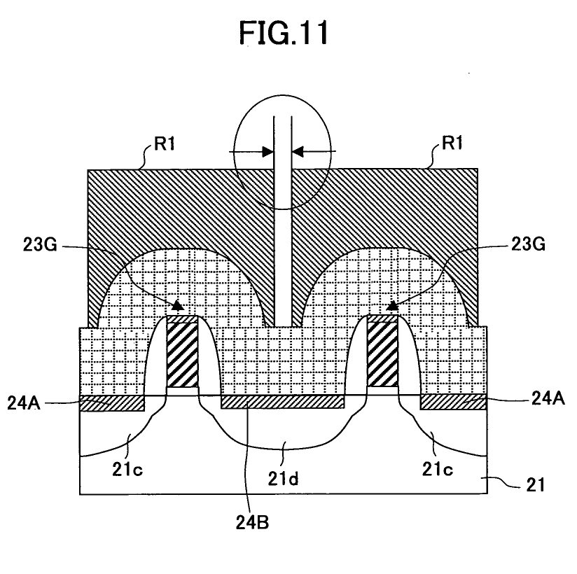

Meanwhile, in a semiconductor integrated circuit in which the n-channel MOS transistors are arranged with large number in such a manner that the diffusion regions 21c and 21d are shared by adjacent n-channel MOS transistors, it becomes necessary to decrease the interval between adjacent resist patterns R1 as shown in FIG. 11 at the time of patterning the SiN film 25 with the process of FIGS. 10A and 10B when the thickness of the SiN film 25 is large relative to the repetition pitch of the n-channel MOS transistors. In such a case, however, there arises a problem that exposure of such closely neighboring resist patterns R1 is difficult because of the proximity effect.

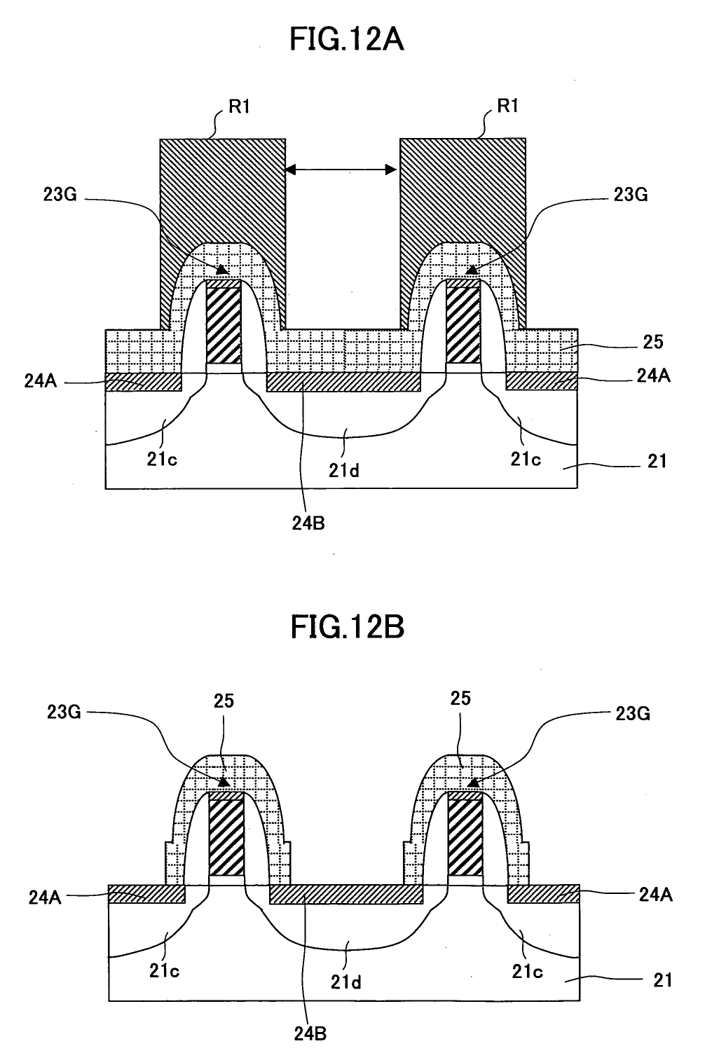

In such a case, it becomes possible to pattern the individual resist patterns R1 by restricting the thickness of the SiN film 25 as shown in FIG. 12A. Thereby, it becomes possible to decrease the thickness of the SiN film in the part located between adjacent MOS transistors.

FIG. 12B shows a structure according to he second embodiment of the present invention in which the SiN film 25 is patterned by using the resist pattern R1 of FIG. 12A.

Referring to FIG. 12B, it will be noted that the SiN film 25 is removed in the present embodiment from the diffusion regions 21c and 21d covered by the silicide layer 24A or 24B and shared by the adjacent MOS transistors, and as a result, the SiN film 25 form discrete patterns on the respective gate structures 23G.

In FIG. 12B, it is preferable to limit the thickness of the SiN film 25 to be 80 nm or less in the case the n-channel MOS transistors are to be formed repeatedly with the pitch of 200 nm.

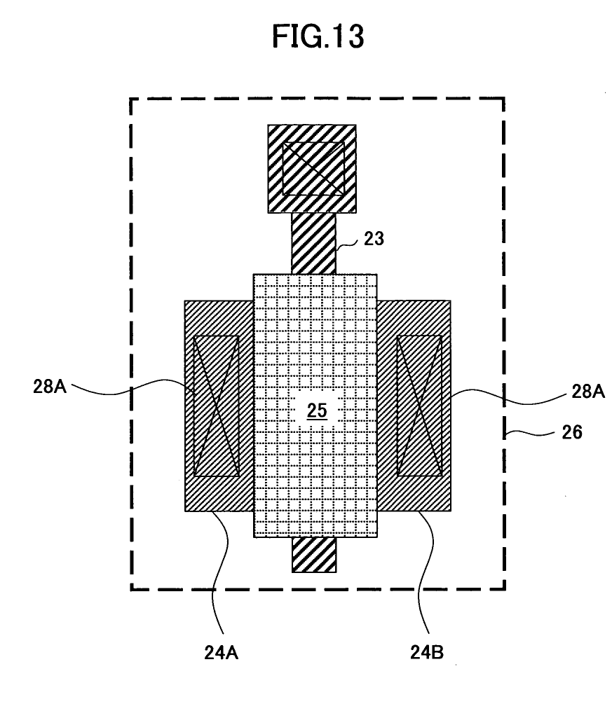

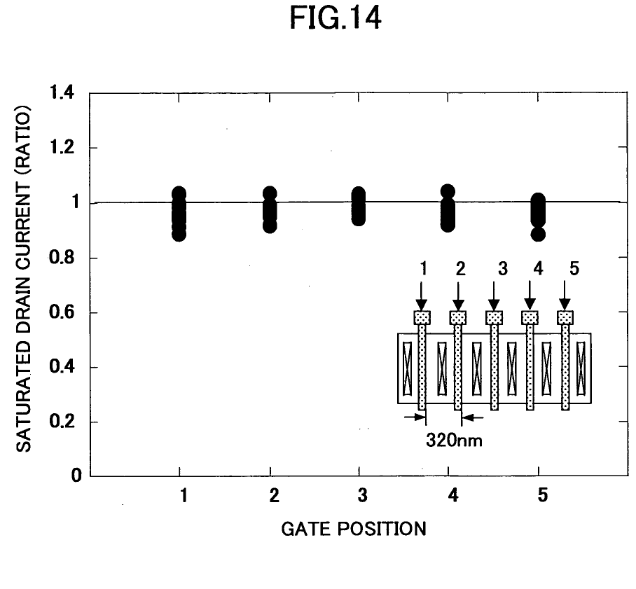

FIG. 13 is a plan view showing one of the n-channel MOS transistors of FIG. 12B, while FIG. 14 shows the value of the saturated drain current, for the case when five such n-channel MOS transistors are formed with a pitch of 320 nm in a device region defined on a silicon substrate by a device isolation region, of the respective MOS transistors in the form of ratio.

Referring to FIG. 13, it can be seen that the silicide regions 24A and 24B are formed at both lateral sides of the SiN pattern 25 in correspondence to he diffusion regions 21c and 21d, wherein the silicide regions 24A and 24B are covered with the SiN film 26 represented with the broken line. Further, through the SiN film 26, contact plugs 28A and 28B extend in the upward direction from the silicide regions 24A and 24B. Further, a similar contact is formed at the end part of the gate electrode 23.

Referring to FIG. 14, it is expected that there would appear a difference of saturated drain current, in the case the stress caused by the SiN film 25 is interacting between adjacent transistors, between the device at the central part of the device region and the device at the peripheral part of the device region, while the result of FIG. 14 clearly indicates that there is no substantial difference of saturated drain current between different devices. Thus, the result of FIG. 14 indicates that the stress formed by the SiN pattern in a device is more or less limited to the region right underneath of that device in the device having the construction of FIG. 12B.

### Third Embodiment

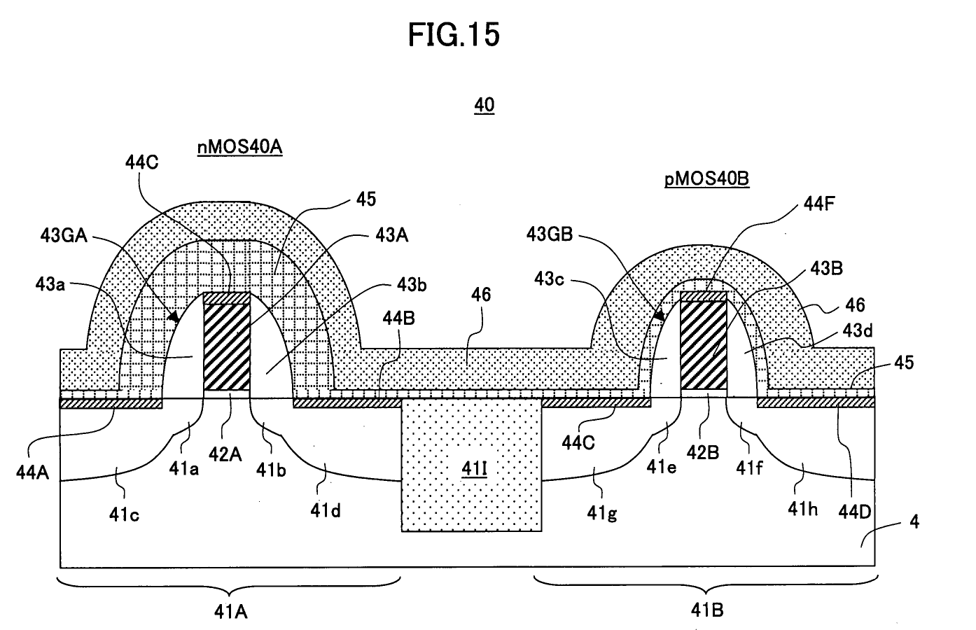

FIG. 15 shows the construction of a CMOS device 40 according to a third embodiment of the present invention.

Referring to FIG. 15, the CMOS device 40 is formed on a silicon substrate 41, wherein the silicon substrate 41 is formed with a device region 41A for an n-channel MOS transistor and a device region 41B for a p-channel MOS transistor by a device isolation structure 41I of STI type.

On the device region 41A, there is formed a gate electrode 43A doped to n+-type in correspondence to a channel region of the n-channel MOS transistor 40A via a gate insulation film 42A of SiON, and the like, and LDD regions 41a and 41b of n-type are formed in the device region 41A at both lateral sides of the gate electrode 43A.

Further, sidewall insulation films 43a and 43b are formed on both sidewall surfaces of the gate electrode 43A, and diffusion regions 41c and 41d of n+-type are formed in the device region 41A at the outer sides of the sidewall insulation films 43a and 43b respectively as the source and drain regions of the n-channel MOS transistor 40A.

In the n-channel MOS transistor 40A, an SiN film 45 is formed on a first gate structure 43GA formed of the gate electrode 43A and the sidewall insulation films 43a and 43b, wherein it should be noted that the SiN film 45 reduces the thickness thereof on the device region 41A in the part outside of the gate structure 43GA. Further, it should be noted that the SiN film 45 extends toward the device region 41B across the device isolation structure 41I.

Further, in the device region 41A, there are formed silicide layers 44A, 44B and 44C respectively on the surfaces of the n+-type diffusion regions 41c and 41d an the surface of the gate electrode 43A, and the silicide layers 44A-44C are covered with the SiN film 45.

On the device region 41B, on the other hand, there is formed a gate electrode 43B doped to p+-type in correspondence to the channel region of the p-channel MOS transistor 40B via a gate insulation film 42B of SiON, and the like, wherein there are formed LDD regions 41e and 41f of p-type in the device region 41B at both lateral sides of the gate electrode 43B.

Further, sidewall insulation films 43c and 43d are formed on respective sidewall surfaces of the gate electrode 43B, and diffusion regions 41g and 41h of p+-type are formed in the device region 41B at respective outer sides of the sidewall insulation films 43c and 43d as source and drain regions of the p-channel MOS transistor 40B.

Further, in the p-channel MOS transistor 40B, the SiN film 45 extending from the device region 41A of the n-channel MOS transistor 40A is formed on the gate structure 43GB formed of the gate electrode 43B and the sidewall insulation films 43c and 43d with the thickness identical with the thickness of the SiN film 45 for the part covering the region outside the first gate structure 43GA.

Further, in the device region 41B, there are formed silicide layers 44D, 44E and 44F respectively on the surfaces of the p+-type diffusion regions 41g and 41h and the surface of the gate electrode 43B. Thereby, the silicide layers 44D-44F are covered also by the SiN film 45.

Further, in the CMOS device 40 of FIG. 15, there is provided a second SiN film 46 acting as an etching stopper film such that the SiN film 46 continuously covers the device regions 41A and 41B.

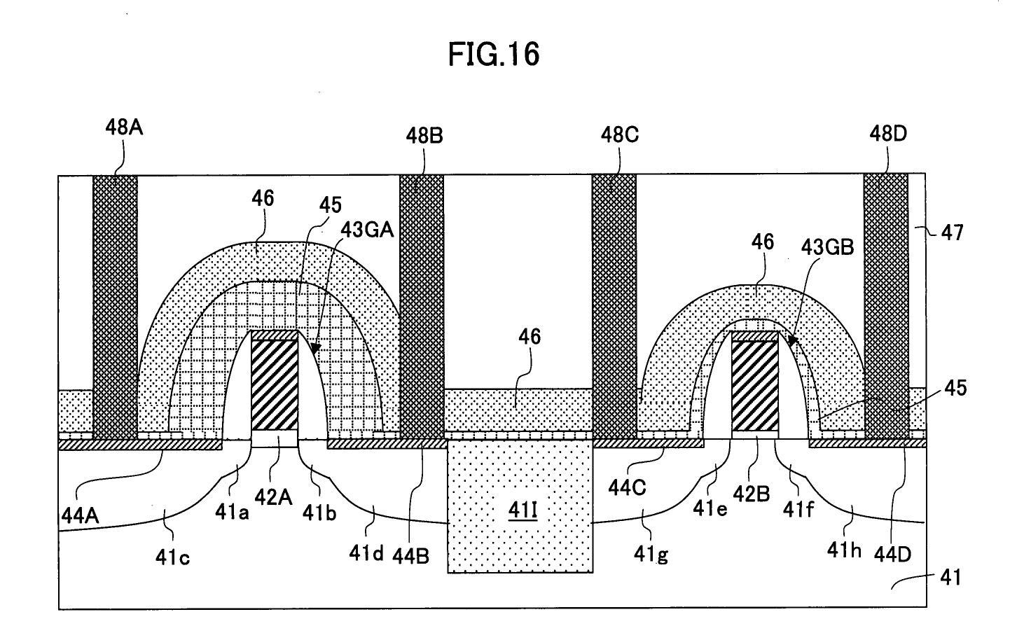

Further, as shown in FIG. 16, there is formed an interlayer insulation film 47 on the SiN film 46, wherein the interlayer insulation film 47 includes contact plugs 48A, 48B, 48C and 48D respectively in contact with the source and drain diffusion regions 41c, 41d, 41e and 41f of the n-channel MOS transistor 40A and the p-channel MOS transistor 40B.

In the CMOS device 40 of FIGS. 15 and 16, the SiN film 45 having the strong tensile stress has a large thickness only in the vicinity of the gate structure 43GA of the n-channel MOS transistor 40A, and thus, the number of the sites on the silicon substrate 41 in which a large tensile stress is applied is reduced. Thereby, the problem of warp of the silicon wafer on which the CMOS device is formed is reduced.

In other words, in the construction of FIGS. 15 and 16, it becomes possible to increase the thickness of the SiN film 45 or the tensile stress in the film as long as the warp of the silicon wafer is in the tolerable range. Thereby, it becomes possible to increase the compressive stress applied to the channel region of the n-channel MOS transistor further.

Further, with the construction of FIGS. 15 and 16, in which the thickness of the SiN film 45 is reduced for the part covering the gate structure 43GB in the p-channel MOS transistor 40B, the compressive stress acting vertically to he substrate surface in the channel region of the p-channel MOS transistor 40B is reduced, and the degradation of characteristics of the transistor 40B is reduced.

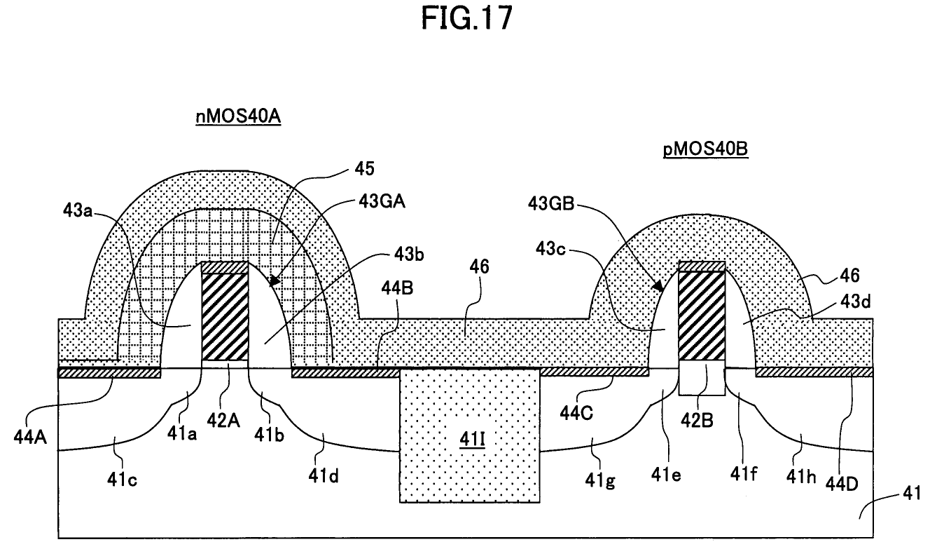

As a modification of the CMOS device 40 of FIGS. 15 and 16, it is also possible to eliminate the SiN film 45 in the outer region of the gate structure 45GA of the n-channel MOS transistor 40A as shown in FIG. 17. In this modification, the sidewall insulation films 43a and 43b constituting the gate structure 43GA make a contact with the SiN film 45, while in the p-channel MOS transistor 40B, the sidewall insulation films 43c and 34d constituting the gate structure 43GB make a direct contact with the SiN etching stopper film 46.

According to the construction of FIG. 17, the SiN film 45 accumulating a strong tensile stress is limited on the gate structure 43GA of the n-channel MOS transistor 40A, and thus, undesirable compressive stress applied perpendicularly to the substrate in the channel region of the p-channel MOS transistor and causes decrease of hole mobility, is reduced further. Further, the warp of the silicon wafer, on which the semiconductor integrated circuit device including the CMOS device 40 is formed, is reduced, while this enables further increase of the stress in the SiN film 45 in the n-channel MOS transistor as long as the warp of the silicon wafer does not exceed the predetermined allowable limit.

### Fourth Embodiment

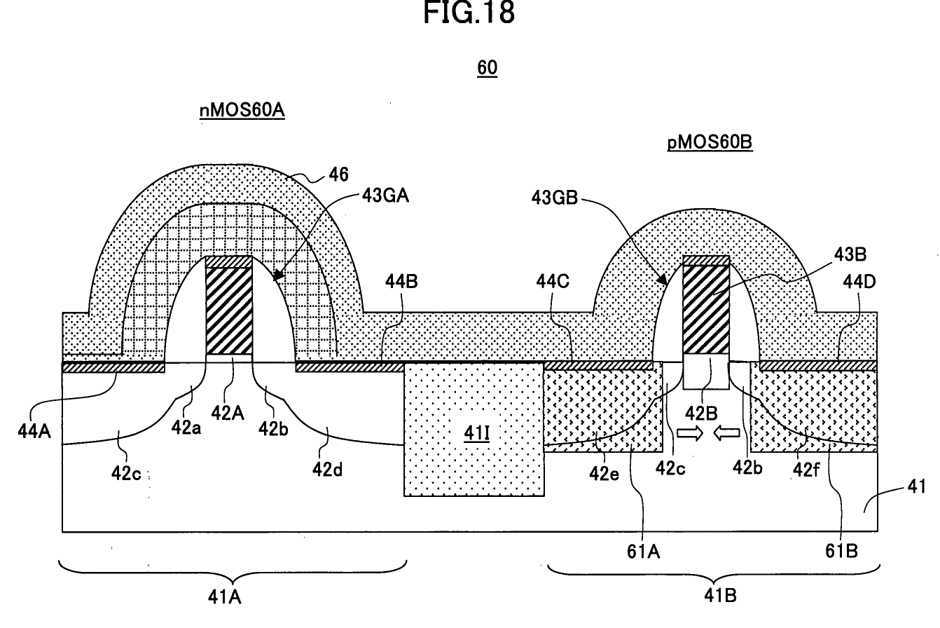

FIG. 18 shows the construction of a CMOS device 60 according to a fourth embodiment of the present invention, wherein those parts corresponding to the parts described previously are designated by the same reference numerals and the description thereof will be omitted.

Referring to FIG. 18, the CMOS device 60 includes an n-channel MOS transistor 60A and a p-channel MOS transistor 60B respectively on the device region 41A and the device region 41B of the silicon substrate 41. Thereby, it will be noted that, while the n-channel MOS transistor 60A and the p-channel MOS transistor 60B have the construction similar to those of the n-channel MOS transistor 40A and the p-channel MOS transistor 40B, there exists a difference in that there are formed SiGe layers 61A and 61B in the device region 41B of the p-channel MOS transistor 60B epitaxially at both lateral sides of the gate electrode 43B.

It should be noted that such SiGe layers 61A and 61B have a lattice constant larger than that of Si constituting the silicon substrate 41, and thus, there is applied a compressive stress acting parallel to the substrate surface in the channel region of the p-channel MOS transistor formed right underneath the gate electrode 43B.

The compressive stress acting parallel to the substrate surface causes an increase of hole mobility in the channel region of the p-channel MOS transistor 60B, and as a result, there is caused an increase of the drain saturation current in the p-channel MOS transistor 60B and hence an increase of the operational speed of the p-channel MOS transistor 60B.

### Fifth Embodiment

Further, the inventor of the present invention has investigated the stress distribution occurring in a MOS structure, based on the conventional MOS transistor structure of FIG. 1, for the case the SiN stress-accumulating film 15 is formed of lamination of plural SiN film elements, by way of simulation.

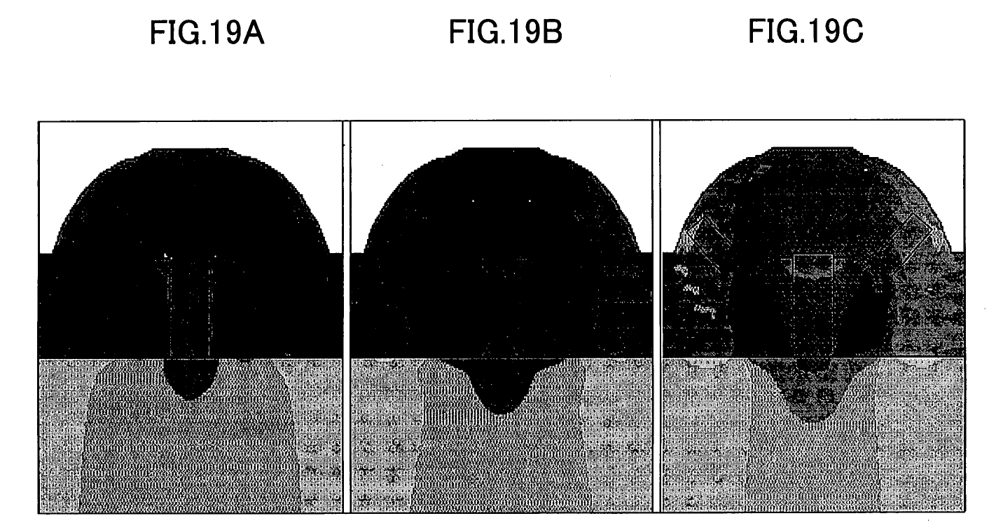

FIGS. 19A-19C show the result of such stress analysis, wherein FIG. 19A shows the case in which the SiN stress-accumulating film 15 is formed of a single SiN film, while FIG. 19B shows the case in which the SiN film 15 is formed of lamination of two SiN film elements. Further, FIG. 19C shows the case in which the SiN film 15 is formed of lamination of five SiN film elements. In any of these cases, the simulation has been conducted under the condition that the SiN stress-accumulating film 15 has a total thickness of 100 nm and that each SiN film element accumulates therein a tensile stress. In any of these models, each SiN film elements may be formed by an LPCVD process under the condition similar to the one explained before. Thereby, the substrate may be taken out, each time an SiN film element is formed, from the processing chamber to an adjacent substrate transportation chamber and cools the substrate to the room temperature.

Referring to FIGS. 19A-19C, it is noted that the stress distribution in the MOS structure right underneath the gate electrode changes significantly depending on whether the SiN film 15 is formed of a single SiN film or it is formed in the form of lamination of plural SiN films, even though the total thickness of the SiN film 15 is the same.

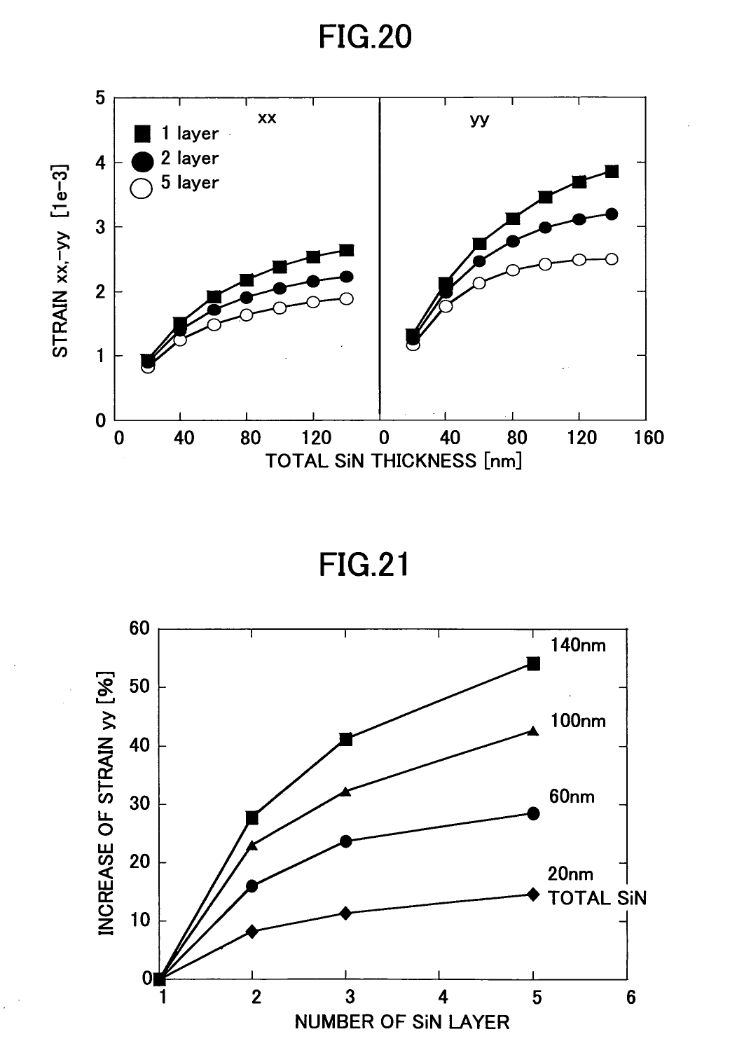

FIG. 20 shows the tensile stress xx induced in the channel region parallel to the substrate surface and the compressive stress yy induced in the channel region perpendicularly to the substrate surface, for the case in which the SiN film 15 is formed by: (a) a single SiN film; (b) lamination of two SiN film elements; and (c) lamination of five SiN elements, wherein the total thickness of the SiN film 15 is changed in FIG. 20 within the range of 20-140 nm.

Referring to FIG. 20, there occurs naturally an increase of magnitude of the stress xx and the stress yy with increase of the total thickness of the SiN film 15, wherein it is also noted that the magnitude of the stress increases in the case the SiN film 15 is formed of a lamination of plural, thin SiN film elements, as compared with the case in which the SiN film 15 of the same thickness is formed of a single SiN layer.

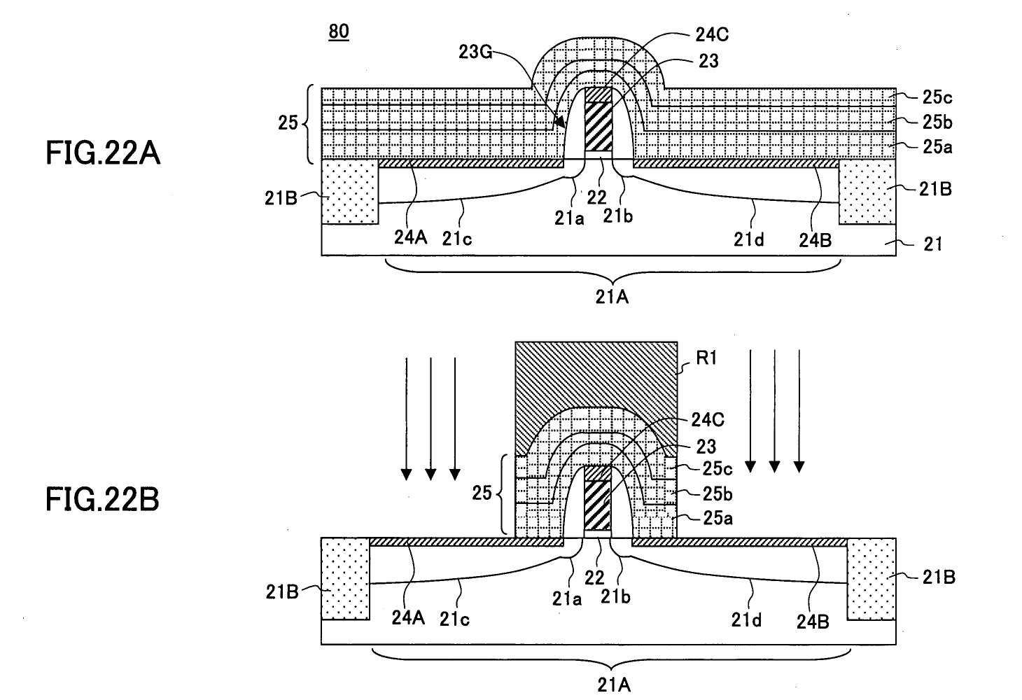

FIG. 21 shows the magnitude of the compressive stress yy induced in the channel region in the direction perpendicularly to the substrate surface for the case the number of the SiN film elements is changed for the SiN film 15 of various thicknesses.

Referring to FIG. 21, it can be seen that the magnitude of the compressive stress yy increases significantly by increasing the number of the SiN film elements constituting the SiN film 15. Further, it can be seen that, with increase of the total thickness of the SiN film 15, the effect of stress increase caused in increase of the SiN film elements constituting the SiN film 15 is enhanced.

The result of FIGS. 20 and 21 indicates that, in the case the stress-accumulating insulation film 25 or 45 is formed in the form of lamination of large number of SiN film elements in each embodiment explained previously, there should occur an increase of magnitude of the compressive stress acting perpendicularly to the substrate surface in the channel region of the n-channel MOS transistor.

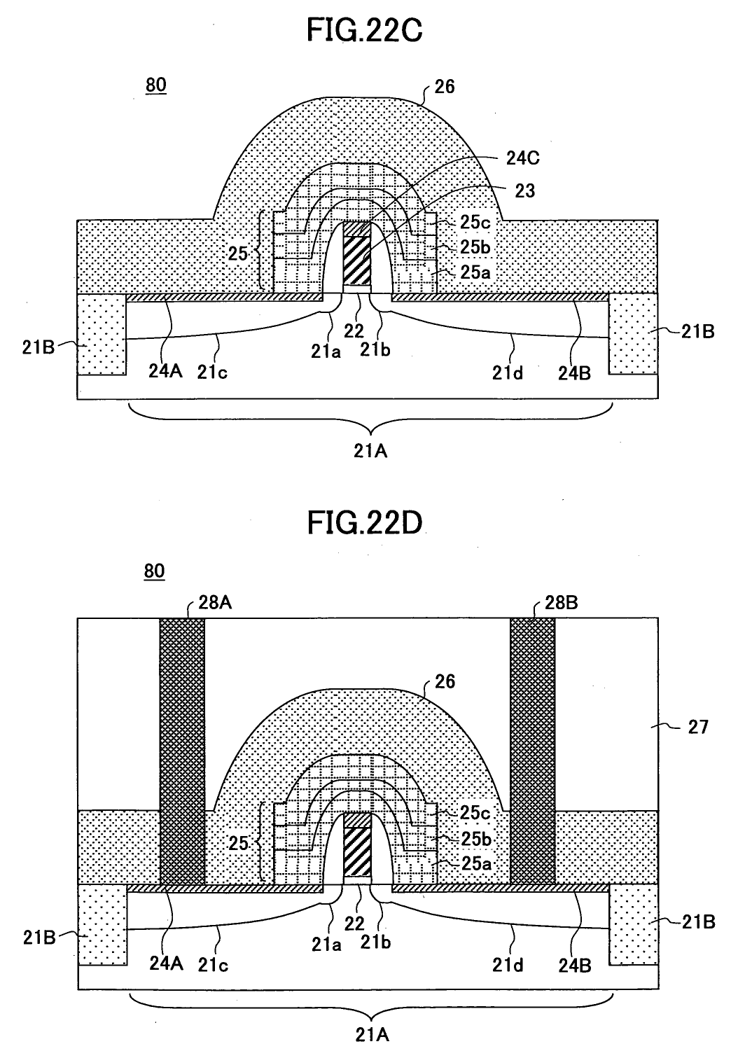

FIGS. 22A-22D show the fabrication process of an n-channel MOS transistor according to a fifth embodiment of the present invention in which the foregoing effects are taken into consideration, wherein those parts explained previously are designated by the same reference numerals and the description thereof will be omitted.

Referring to FIG. 22A, SiN films 25a-25c, each accumulating therein a tensile stress of 1.5 GPa, are formed on the silicon substrate 21 so as to form the SiN film 25, such that the SiN film 25 covers the gate structure 23G with a total thickness of 120 nm, for example. Further, in the step of FIG. 22B, the SiN film 25 is removed at the outer part of the gate structure by using a resist pattern R1.

Further, in the step of FIG. 22C, the SiN film 25 is deposited uniformly on the structure of FIG. 22B as an etching stopper, and the interlayer insulation film 27 is formed on the structure of FIG. 22C in the step of FIG. 22D so as to cover the SiN film 26. Further, contact holes are formed in the interlayer insulation film 27 in correspondence to the diffusion regions 21c and 21d while using the SiN film 26 as an etching stopper, and the diffusion regions 21c and 21d are exposed at the respective contact holes. Further, the conductive plug 28A is formed in one of such contact holes such that the conductive plug 28A makes a contact with the diffusion region 21c via the silicide layer 21A, and the other conductive plug 28B is formed in the other contact hole such that the conductive plug 28B makes a contact with the diffusion region 21d via the silicide layer 21B.

In the n-channel MOS transistor of the present embodiment, it is possible to induce a large compressive stress in the channel region even in the case the SiN film 25 has a relatively small thickness, and thus, the problem explained with reference to FIG. 14 is reduced even when the n-channel MOS transistors are formed on the substrate with a small repetition pitch. In other words, it becomes possible to form the n-channel MOS transistors reputedly on the substrate with a very small pitch with the present embodiment. In FIG. 21, cases are shown in which the number of the SiN film elements constituting the SiN film is changed within the range of 1-5 under the condition that the total thickness of the SiN film 25 is changed within the range of 20-140 nm. In any of these cases, it can be seen that the effect of the multilayer construction of the SiN film 25 is attained. Further, from FIG. 21, it is obvious that the foregoing effect is not limited to the case in which the number of the SiN film elements is in the range of 1-5. Further, it is also obvious that the foregoing effect is limited for the case the total thickness of the SiN film 25 is in the range of 20-140 nm.

Further, a similar construction of the n-channel MOS transistor of the present embodiment is applicable also to the case of the CMOS device 40 or 60 explained before.

### Sixth Embodiment

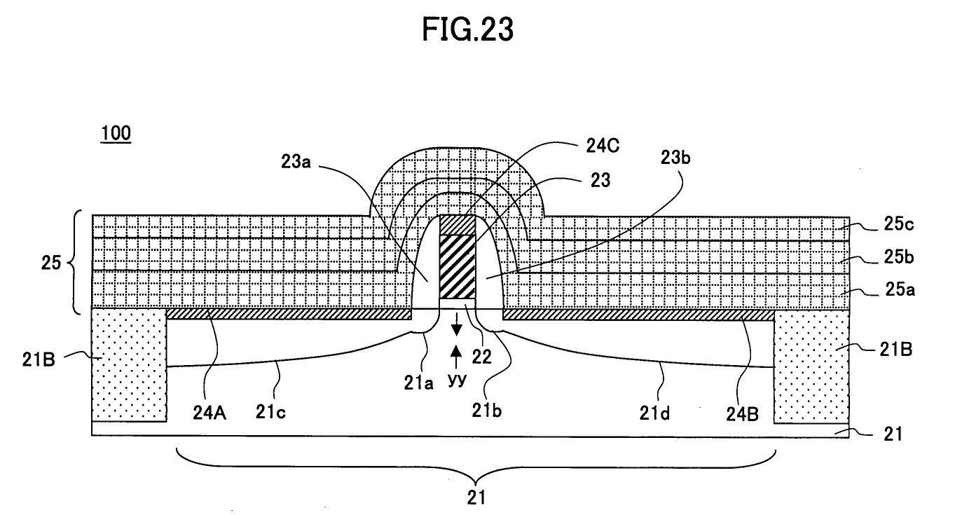

FIG. 23 shows the construction of an n-channel MOS transistor 100 according to a sixth embodiment of the present invention, wherein those parts of FIG. 23 explained previously are designated by the same reference numerals and the description thereof will be omitted.

Referring to FIG. 23, it will be noted that the present embodiment has the construction of FIG. 6B explained previously except that the SiN film 25 is formed of lamination of the SiN films 25a, 25b and 25c.

Each of the SiN films 25a, 25b and 25c accumulates a tensile stress, and thus, it becomes possible to induce a large compressive stress in the silicon substrate 21 in the channel region right underneath the gate electrode in the direction perpendicular to the substrate surface, with a large magnitude hitherto not possible to achieve.

Further, the present invention is not limited to the embodiments described heretofore, but various variations and modifications may be made without departing from the scope of the invention.

What is claimed is:

1. A semiconductor device, comprising:
a semiconductor substrate;
a gate electrode formed on a channel region in said semiconductor substrate via a gate insulation film; and
a pair of diffusion regions formed in said semiconductor substrate at both lateral sides of said gate electrode,
a pair of sidewall insulation films being formed on both sidewall surfaces of said gate electrode,
a stress-accumulating insulation film being formed on said semiconductor substrate so as to cover said gate electrode and said sidewall insulation films, said stress-accumulating insulation film accumulating a stress therein,
said stress-accumulating insulation film including a channel part covering said gate electrode and said sidewall insulation films and outer parts extending outside of said channel part,
said stress-accumulating insulation film having an increased thickness in said channel part as compared with said outer part.

2. The semiconductor device as claimed in claim 1, wherein said stress has an absolute value exceeding 1 GPa.

3. The semiconductor device as claimed in claim 1, wherein said stress-accumulating insulation film has a laminated structure in which plural film elements are laminated.

4. The semiconductor device as claimed in claim 1, wherein said stress-accumulating insulation film has an overall thickness of 20-140 nm in said channel part.

5. The semiconductor device as claimed in claim 1, wherein said stress-accumulating insulation film has a thickness of 80 nm or less in said outer part.

6. The semiconductor device as claimed in claim 1, wherein said stress-accumulating insulation film is removed at said outer part.

7. The semiconductor device as claimed in claim 1, wherein said stress-accumulating insulation film is an SiN film.

8. The semiconductor device as claimed n claim 1, wherein said pair of diffusion regions are formed of an n-type diffusion region.

9. The semiconductor device as claimed in claim 1, wherein another insulation film and an interlayer insulation film are formed consecutively on said stress-accumulating insulation film, and wherein a pair of contact plugs are formed in said interlayer insulation film through said another insulation film respectively in contact with pair of diffusion regions.

10. A CMOS integrated circuit device, comprising:
a semiconductor substrate defined with a first device region and a second device region by a device isolation region;
an n-channel MOS transistor formed in said first device region; and
a p-channel MOS transistor formed in said second device region,
said n-channel MOS transistor comprising: a first gate electrode formed on a first channel region in said first device region via a first gate insulation film; a pair of first sidewall insulation films respectively covering both sidewall surfaces of said first gate electrode; and a pair of n-type diffusion regions formed in said semiconductor substrate at both lateral sides of said first gate electrode;
said p-channel MOS transistor comprising: a second gate electrode formed on a second channel region in said second device region via a second gate insulation film; a pair of second sidewall insulation films respectively covering both sidewall surfaces of said second gate electrode; and a pair of p-type diffusion regions formed in said semiconductor substrate at both lateral sides of said second gate electrode;
wherein there is formed a stress-accumulating insulation film accumulating therein a tensile stress in said first device region so as to cover said first gate electrode and said first sidewall insulation films,
said stress-accumulating insulation film comprising a channel part covering said first gate electrode and said first sidewall insulation films and an outer part outside of said channel part,
said stress-accumulating insulation film having an increased thickness in said channel part as compared with said outer part.

11. The CMOS integrated circuit device as claimed in claim 10, wherein said stress-accumulating insulation film has a laminated structure in which plural film elements are laminated.

12. The CMOS integrated circuit device as claimed in claim 10, wherein said stress-accumulating insulation film has an overall thickness of 20-140 nm in said channel part.

13. The CMOS integrated circuit device as claimed in claim 10, wherein said stress-accumulating insulation film has a thickness of 80 nm or less in said outer part.

14. The CMOS integrated circuit device as claimed in claim 10, wherein said stress-accumulating insulation film further covers said second gate electrode and said second sidewall insulation films in said second device region, said stress-accumulating insulation film having a reduced thickness in said second device region as compared with said channel part in said first device region.

15. The CMOS integrated circuit device as claimed in claim 10, wherein said stress-accumulating insulation film is removed at said outer part and said second device region.

16. The CMOS integrated circuit device as claimed in claim 10, wherein said stress-accumulating insulation film is an SiN film.

17. The CMOS integrated circuit device as claimed in claim 15, wherein there is provided another insulation film in said first device region on said stress-accumulating insulation film in conformity with a shape of said stress-accumulating insulation film and further in conformity with a shape of a surface of said semiconductor substrate and a shape of a second gate structure formed of said second gate electrode and said second sidewall insulation films in said second device region, an interlayer insulation film being formed on said another insulation film, wherein said interlayer insulation film is formed with a pair of contact plugs contacting with said first diffusion regions and a pair of other contact plugs contacting with said second diffusion regions, through said another insulation film.

18. The CMOS integrated circuit device as claimed in claim 17, wherein said another insulation film makes a direct contact with said second sidewall insulation films in said second device region.

19. The CMOS intergraded circuit device as claimed in claim 10, wherein said p-type diffusion regions of said second device region comprises a SiGe mixed crystal.

20. A semiconductor device, comprising:
a semiconductor substrate;
a gate electrode formed on a channel region in said semiconductor substrate via a gate insulation film; and
a pair of diffusion regions formed in said semiconductor substrate at both sides of said gate electrode,
wherein there are formed sidewall insulation films on both sidewall surfaces of said gate electrode, and
wherein there is formed a stress-accumulating insulation film accumulating therein a stress so as to cover said gate electrode and said sidewall insulation films, said stress-accumulating insulation film having a laminated structure in which plural insulation films each accumulating a stress having a common sign are laminated.
